(19) United States
(12) Patent Application Publication
(10) Pub. No.: US 2026/0173776 A1
(43) Pub. Date: Jun. 18, 2026

(54) PHASE CHANGE MEMORY (PCM) CELL WITH THERMOELECTRIC HEATING AND COOLING

(71) Applicant: International Business Machines Corporation, Armonk, NY (US)

(72) Inventors: Guy Moshe Cohen, Ossining, NY (US); Takashi Ando, Eastchester, NY (US); Nanbo Gong, White Plains, NY (US)

(21) Appl. No.: 18/981,473

(22) Filed: Dec. 14, 2024

(51) Int. Cl. H10N 70/00; G11C 13/00; H10B 63/00; H10B 63/10; H10N 10/852; H10N 70/20

(52) U.S. Cl. CPC H10N 70/8613; G11C 13/0004; G11C 13/004; G11C 13/0069; H10B 63/10; H10B 63/24; H10N 10/852; H10N 70/231; H10N 70/841; H10N 70/8828; G11C 2013/0045; G11C 2013/0078; G11C 2013/008

(57) ABSTRACT

A phase change material (PCM) array includes a plurality of word lines, a plurality of bit lines, and a plurality of PCM cells, in which each bit line is bridged to a word line by a PCM cell, of the plurality of PCM cells, in series with a transistor. Each PCM cell includes a plurality of layers of a thermoelectric material and a plurality of layers of a phase change material in which one of the plurality of layers of the thermoelectric material is a highly oriented seeding layer and the plurality of layers of the thermoelectric material and the plurality of layers of the PCM are alternating layers within the PCM cell.

### BACKGROUND

The present invention relates generally to the electrical, electronic, and computer arts, and, more particularly, to phase change memory (PCM) used in non-volatile memory applications and the like.

Phase change memory has emerged as a viable option for various applications such as machine learning. For example, phase change memory can be used to store weights of a neural network for artificial intelligence (AI) applications. A phase change memory can include a thin layer of a phase change memory material, or phase change material, with two electrodes at the end of the phase change material.

Phase change memory employs the phase change material (also abbreviated as PCM; the skilled artisan will appreciate from the context whether “memory” or “material” is intended) that can exist in two phases, namely, a crystalline phase and an amorphous phase. One exemplary class of phase change materials includes germanium—antimony—tellurium (GST) alloys, which are a type of phase change material from the general group of chalcogenide glasses. GST225 (Ge₂Sb₂Te₅) is one non-limiting example. Phase change memory cells can store a bit (0 or 1) by changing the phase of the phase change material. A typical device has phase change material sandwiched between two contacts. If the phase change material is in the crystalline phase, the phase change material is relatively conductive, and passes a relatively large current. If the phase change material is in the amorphous phase, the phase change material is relatively resistive, and passes a relatively low current. Phase-change memory is non-volatile; once the material is crystalline, it stays crystalline; once the material is amorphous, it stays amorphous (provided the material is kept below the crystallization temperature).

Typically, in an operation of programming a phase change memory, electrical pulses are applied through the chalcogenide material to generate local joule heating, where the phase change material near an electrode contact region can be changed to either the crystalline or amorphous state.

### BRIEF SUMMARY

Principles of the invention provide a phase change memory with thermoelectric heating and cooling. In one aspect, an exemplary phase change material (PCM) array including a plurality of word lines, a plurality of bit lines, and a plurality of PCM cells in which each bit line is bridged to a word line by a PCM cell, of the plurality of PCM cells, in series with a transistor. Each PCM cell including a plurality of layers of a thermoelectric material and a plurality of layers of a phase change material (PCM), in which one of the plurality of layers of the thermoelectric material is a highly oriented seeding layer and the plurality of layers of the thermoelectric material and the plurality of layers of the PCM are alternating layers within the PCM cell.

In another aspect, an exemplary method of operating a memory cell includes receiving, by circuitry, a request to perform a memory write operation of a phase change memory (PCM) cell and responsive to receiving the request to perform the memory write operation, selecting, by the circuitry, a first polarity of a current pulse between a top electrode and a bottom electrode of the PCM cell. Receiving, by the circuitry, a request to perform a memory read operation of the PCM cell, and responsive to receiving the request to perform the memory read operation, selecting, by the circuitry, a second polarity of the current pulse between the top electrode and the bottom electrode of the PCM cell. In which selecting the first polarity of the current pulse can cause a superlattice of thermoelectric material of the PCM cell to heat the PCM cell and selecting the second polarity of the current pulse can cause the superlattice of thermoelectric material of the PCM cell to cool the PCM cell.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments can provide a phase change memory (PCM) cell that, at the time scale of PCM device operation (˜50 ns), has thermoelectric cooling for reduced read disturb and can enable the use of voltage and/or current amplitude levels which can provide for minimal signal to noise ratio during a memory read, and has thermoelectric heating for RESET/SET assist and that can provide for a low reset current (low pulse amplitude), minimal energy for programming, and a low resistance drift:
by forming a highly oriented seeding layer to facilitate growth of fiber-textured PCM material,
by utilizing the highly oriented seeding layer as a template layer,
by facilitating the formation of van der Waals gaps,
by forming alternating layers of phase change material and thermoelectric material,
by forming a superlattice of thermoelectric material,
by forming thermoelectric junctions between the phase change material and the thermoelectric material,
by choosing a current directionality or a polarity of a current pulse dependent upon performing a memory read operation or a memory write operation,
by directing a current pulse through the PCM cell such that thermoelectric junctions are cooling the device when performing a memory read operation,
by directing a current pulse through the PCM cell such that thermoelectric junctions are heating the device when performing a memory write (e.g., RESET/SET) operation,
by maintaining an amorphous phase by ending a current pulse abruptly to cool the material in the amorphous phase, as opposed to a crystalline phase.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 shows an embodiment of a phase change memory cell, according to an aspect of the invention;

FIGS. 2-5 show an exemplary process for manufacturing a phase change memory cell according to the embodiment of FIG. 1, according to an aspect of the invention;

FIGS. 6A and 6B show a current polarity of a phase change memory cell, according to an aspect of the invention;

FIG. 7 shows a cross-section view of a mushroom PCM cell, according to an aspect of the invention;

FIGS. 8A and 8B show a cross-bar array of PCM cells, according to an aspect of the invention;

FIG. 9 illustrates a computing environment according to an embodiment of the present invention (e.g., for implementing a design process such as that of FIG. 10); and

FIG. 10 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

One or more embodiments advantageously provide a PCM cell with alternating layers of a phase change material (PCM) and a thermoelectric material, sandwiched between two conductors (e.g., a top and bottom electrode). In one or more embodiments, the first layer of thermoelectric material is a highly oriented seeding layer that facilitates growth of a fiber-textured PCM layer. Typically, the top conductor (i.e., electrode) is larger than the bottom conductor (i.e., electrode). A current direction (e.g. polarity) between the two conductors can be dependent upon a desired performance of the PCM cell, such as a read operation or a write/program operation, etc. As such, depending on the current direction (e.g., polarity), the thermoelectric layers of the PCM cell can heat or cool the PCM cell, enhancing performance of the PCM cell.

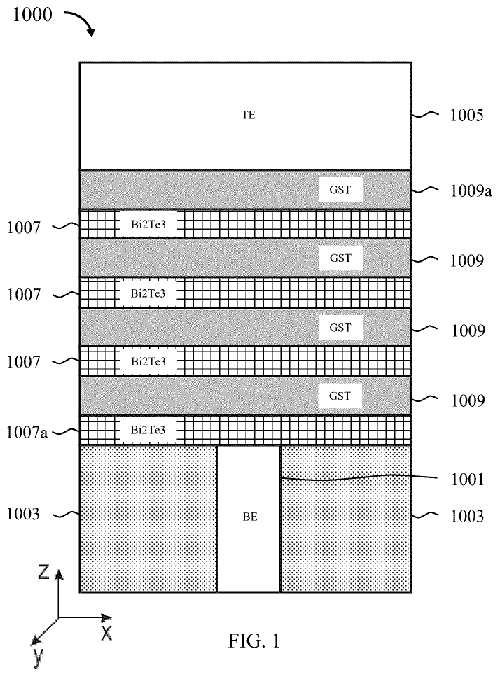

Consider now an exemplary PCM cell structure. Referring to FIG. 1, an embodiment of a PCM cell 1000 is illustrated. The PCM cell 1000 can include a bottom electrode 1001 and a top electrode 1005. The bottom electrode 1001 can be substantially smaller in area than the top electrode 1005. That is, in some nonlimiting embodiments, the bottom electrode can have a diameter of approximately 30-40 nm and the top electrode can have a width of approximately 100 nm and a length of approximately 100 nm, though examples are not so limited and other sizes of electrodes can be contemplated. An array including a plurality of the PCM cells 1000 can include circuitry to cause an electrical pulse to be generated and be applied to one electrode or to the other. For example, a pulse can be applied to the top electrode 1005 or to the bottom electrode 1001, thus allowing the device to operate with positive or negative pulse polarity. Because the contact area of the bottom electrode 1001 is smaller than the contact area of the top electrode 1005 and the current from the pulse can spread out further when a contact area is greater (such as the top electrode 1005 contact area), there can be a larger current density at the contact area of the bottom electrode 1001 than the top electrode 1005. Note, that the terms “bottom” and “top” can be used to indicate relative positioning of the electrodes to each other and other elements and/or structures within the embodiments and not are necessarily indicative of relative elevation in space.

In some embodiments, the PCM cell 1000 can include an insulator 1003 (i.e., insulating layer). The bottom electrode 1001 can be embedded in the insulator 1003. That is, in one or more embodiments, the insulator 1003 can fill an area around the bottom electrode 1001 (e.g., as illustrated in FIG. 1, for example, as being on both a left side and a right side of the bottom electrode 1001) and thus the insulator 1003 can be directly adjacent to the bottom electrode 1001. The insulator 1003 can be made of silicon-nitride, silicon-oxide (SiOₓ), (silicon dioxide (SiO₂) is a non-limiting example) or low-K dielectric, though examples are not so limited and the insulator 1003 can be made of any material suitable for use in PCM cell 1000 structures.

As further illustrated in FIG. 1, the PCM cell 1000 can further include a layer of thermoelectric material 1007 and a layer of PCM 1009. In one or more embodiments, the thermoelectric material 1007 can be bismuth—telluride (Bi₂Te₃) and the PCM 1009 can be germanium—antimony—tellurium (GST). The layer of thermoelectric material 1007 and the layer of PCM 1009 can form a thermoelectric junction, as described in further detail herein. In some embodiments, the PCM cell 1000 can include a plurality of layers of the thermoelectric material 1007 and a plurality of layers of the PCM 1009. The PCM cell 1000 can have layers that alternate between the thermoelectric material 1007 and the PCM 1009. That is, the layers can include a superlattice of thermoelectric material 1007 and PCM material 1009. For example, a first layer can be a layer of thermoelectric material 1007a. The first layer of thermoelectric material 1007a can be located directly adjacent to or abutting (e.g., above as illustrated in FIG. 1) the bottom electrode 1001 and the insulator 1003. A second layer can be a layer of PCM 1009 located directly adjacent to or abutting (e.g., above as illustrated in FIG. 1) the first layer, opposite the bottom electrode 1001 and the insulator 1003. The third layer can be a layer of thermoelectric material 1007 located directly adjacent to or abutting (e.g., above as illustrated in FIG. 1) the second layer, opposite the first layer. The fourth layer can be a layer of PCM 1009 located directly adjacent to or abutting (e.g., above as illustrated in FIG. 1) the third layer, opposite the second layer. The layers can continue in an alternating fashion. Eight layers are illustrated in FIG. 1, though examples are not so limited and more than eight or less that eight layers can be contemplated.

In some embodiments, as previously described, the first layer can be a thermoelectric material 1007a directly adjacent to or abutting the bottom electrode 1001 and the insulator 1003. The thermoelectric material 1007a of the first layer can be a seeding layer. In some examples, the thermoelectric material 1007a of the first layer can be a highly oriented seeding layer. The highly oriented material can be oriented in a direction substantially perpendicular to the bottom electrode 1001 and the top electrode 1005 or substantially perpendicular in the Z direction. The seeding layer 1007a can enable subsequent layers to be highly oriented (e.g. fiber texture).

As further illustrated in FIG. 1, in one or more embodiments, the PCM cell 1000 can include an even number of layers of the plurality of layers of the thermoelectric material 1007 and the plurality of layers of the PCM 1009. As such, the first layer (i.e., the layer directly adjacent to or abutting the bottom electrode 1001 and the insulator 1003) can be a layer of thermoelectric material 1007a and the last layer (i.e., the layer directly adjacent to or abutting the top electrode 1005) can be a layer of PCM 1009a. Accordingly, the plurality of layers of the thermoelectric material 1007 and the plurality of layers of PCM 1009 can reside between the bottom electrode 1001 (and insulator 1003) and the top electrode 1005. That is the bottom electrode 1001 and the insulator 1003 can be separated from the top electrode 1005 by the alternating layers of thermoelectric material 1007 and PCM 1009. Below the bottom electrode 1001 and the insulator 1003 there can be layers of interconnects (not shown) and a substrate (not shown) with circuits built of transistors (such as metal-oxide semiconductor field effect transistors (MOSFETs), as would be apparent to the skilled artisan, given the teachings herein).

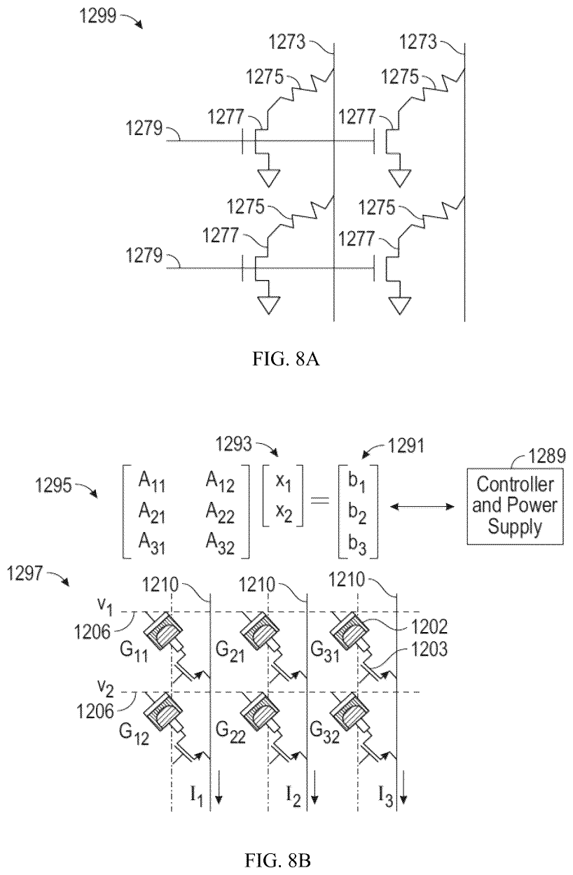

Bits of data (representing logical “0” and “1”) can be written to and stored on PCM cells in a PCM array of a device (such as array 1299 illustrated in FIG. 8A). To write a bit, the bit is selected by applying a voltage to a word line (such as word lines 1279 illustrated in FIG. 8A) to turn on a corresponding transistor and then pulsing a bit line (such as bit line 1273 illustrated in FIG. 8A) with a SET or a RESET pulse.

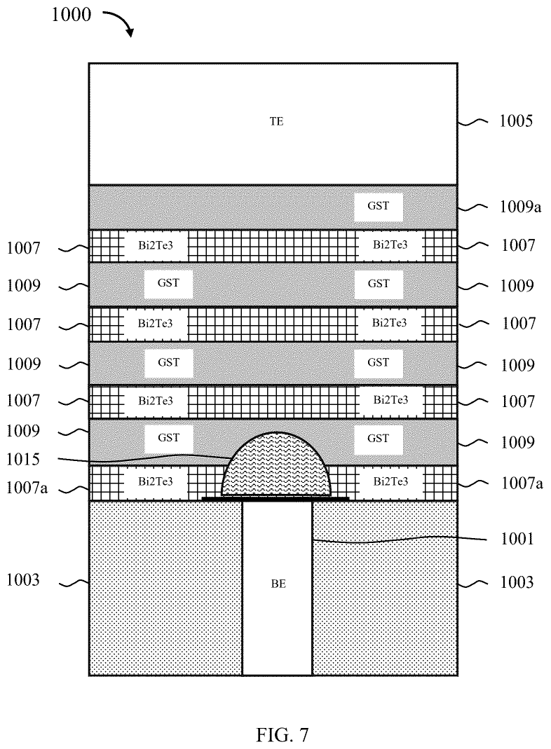

Regarding RESET, this operation typically involves applying a high current pulse to the device (“high” can mean providing enough energy to melt the area adjacent to the bottom electrode 1001, as illustrated in FIG. 7). In some examples, material within the molten region can intermix; however, examples are not so limited. The RESET pulse can be quickly quenched/shut down to force a fast cooling of the melt, which then solidifies in an amorphous phase (i.e., RESET state). If the pulse is drawn as a function of time, quenching means that the trailing edge of the pulse drops abruptly. This abrupt drop-off causes the molten material to quickly cool off without crystalizing. The effect is that the bottom electrode 1001 (which is one of the contacts) is covered with a dome (e.g., dome 1015 as shown in FIG. 7) of (high-resistance) amorphous material, which blocks current. The dome and bottom electrode 1001 together form a “mushroom shape” including the bottom electrode 1001 as the “stem” of the mushroom.

However, if the current pulse tapers slowly (by having a long trailing edge) the melt will solidify in the crystalline phase (i.e., SET state) as it would have sufficient time to crystallize. Note that the dome of amorphous PCM cell 1000 can re-crystallize upon SET pulse using the surrounding crystalline material as a template. In some examples, when the amorphous dome is crystallized by a SET pulse it is no longer arranged as a superlattice of alternating layers, but is it is a homogeneous intermixed material, and the material is highly ordered (fiber texture). Still in further examples, for some thermoelectrical materials the superlattice structure can be preserved after RESET if only the PCM 1009 is melted.

It can be desirable for PCM devices to have a low RESET current. One technique to achieve this is to make the bottom electrode 1001 as small as possible. The dome can form at the bottom of the PCM cell 1000 (e.g., adjected to the bottom electrode 1001) because that is where the current density is greatest. The highest current density is right over the bottom electrode 1001. Typically, the smaller the diameter of the bottom electrode 1001, the better (higher current density means lower RESET current). The diameter of the bottom electrode 1001 should typically be the smallest the given technology can achieve (in current technology the bottom electrode 1001 is about 30 nm in diameter; that will change (decrease) as fabrication technology advances). Generally, in one or more embodiments, the bottom electrode 1001 can have a diameter of 30-40 nm (20 nm is believed to be better if available under the particular technology node and process conditions) and the top electrode 1005 can have a diameter of a hundred to a few hundred nm.

In one or more embodiments, circuitry can set a polarity of the current between the bottom electrode 1001 and the top electrode 1005 to cause generated current to flow from the top electrode 1005, through thermoelectric junctions (e.g., through the PCM 1009 and thermoelectric material 1007 as further described herein), to the bottom electrode 1001, causing a superlattice of thermoelectric material of the PCM cell 1000 to heat the PCM cell 1000. Heating of the PCM cell 1000 can assist in melting of the area adjacent to the bottom electrode 1001, thus reducing the RESET current used. Heating the PCM cell 1000 when PCM 1009 is amorphous is likely to decrease the resistance of the PCM cell 1000. However, when the PCM cell 1000 is in the SET state (crystalline PCM 1009 which is metallic like due to large number of carriers) a temperature increase is likely to increase resistance. Note that, given the teachings herein, the skilled person can determine required currents and waveforms for particular geometries using known techniques such as coupled thermal-electrical finite element analysis. The maximum current density is where the bottom electrode 1001 meets thermoelectric material 1007a. The material melts, forming the dome.

In one or more embodiments, when carrying out melting and recrystallization using a rapid quench, a second, smaller amplitude pulse can be applied, which anneals the material above the crystallization temperature but does not need to melt it. For example, for GST 225, the crystallization temperature is about 165 C. In another approach, a RESET pulse can be employed but without use of an abrupt trailing edge; rather, cool slowly to recrystallize the area adjacent to the bottom electrode 1001.

Further regarding the “rapid” quench, the same has to be fast enough such that the melt solidifies in the amorphous phase. This varies depending on the PCM material used. For example, for GST 225, the trailing edge of the RESET pulse is on the order of a few nanoseconds or less. Further regarding the “smaller amplitude” pulse, the same is defined as a pulse that would lead to crystallization of the PCM material. For example, for GST 225, it is typically a pulse that has a long trailing edge of several tens of nanoseconds or more. Again, given the teachings herein, the skilled person can determine required currents and waveforms for particular geometries using known techniques such as coupled thermal-electrical finite element analysis.

The bits of data written to and stored on the PCM cells in an array of PCM cells can be read to determine what state a given PCM cell 1000 is in, i.e., RESET or SET. Note that the read operation is typically done with a low voltage to avoid an accidental writing of the bit, or a so-called “read disturb.” That is, a low current can minimize the heat created during the read operation. High heat can anneal the device and cause a RESET state to become a SET state going from amorphous to crystalline and thus creating a read disturb. During a read disturb, data stored in the device is lost. Low current during the read operation can prevent occurrences of read disturb. However, too low of a current amplitude can prevent an adequate read of the data as reading with a too low of a current amplitude can result in difficultly distinguishing the signal from noise within the PCM cell 1000. Thus, too high of current (i.e., current amplitude) during the read operation can change the device state and too low of current during the read operation can potentially yield an erroneous read output due to noise. As such, there is a limit to how low the current amplitude can be, or a threshold current amplitude level. In at least one nonlimiting example, the read current can be about 1-40 μA for devices in the SET state and about 0.04-0.4 μA for devices in the RESET state.

In one or more embodiments, setting a polarity of the current pulse between the bottom electrode 1001 and the top electrode 1005 to cause the current to flow from the bottom electrode 1001, through thermoelectric junctions (e.g., through the thermoelectric material 1007 and the PCM 1009 as further described herein), to the top electrode 1005, can cause the superlattice of thermoelectric material of the PCM cell 1000 to cool the PCM cell 1000. Cooling of the PCM cell 1000 assists in prevention of crystallization of the area adjacent to the bottom electrode 1001. As such, the current amplitude utilized during the read operation can be increased without negatively affecting the state of the PCM cell 1000 and without causing a read disturb. Accordingly, the ability to increase the current amplitude can prevent noise from disrupting a read of the PCM cell 1000. Further or in the alternative, a voltage applied can be increased, improving the signal to noise ratio of the read operation. Typical voltage for read operation is 0.2-0.4 V. Typical write operation (when the device is in RESET state) depends on the device threshold voltage. Usually, the threshold voltage can be about 1-1.2 volts. As such the read voltage should not exceed the threshold voltage. Note that, given the teachings herein, the skilled artisan can determine required currents and waveforms for particular geometries using known techniques such as coupled thermal-electrical finite element analysis.

Accordingly, the superlattice of thermoelectric material 1007 used herein, in conjunction with controlling the directionality of the current (i.e., polarity of the current pulse), can provide a safe read of the PCM cell 1000 without the occurrence of a read disturb as well as assist in a programming operation (i.e., write operation such as RESET and SET) of the PCM cell 1000. Note that the thermoelectric effect can be based on free carriers (e.g., electrons); thus, fast cooling and heating can occur. Further, the effect on heating during the write operation can be moderate, as heating is proportional to the square root of the current (I²R) while the thermoelectric effect is linear with the current; the effect on cooling during the read operation can be more pronounced, as the read current is small (i.e., 0.1), I²<I.

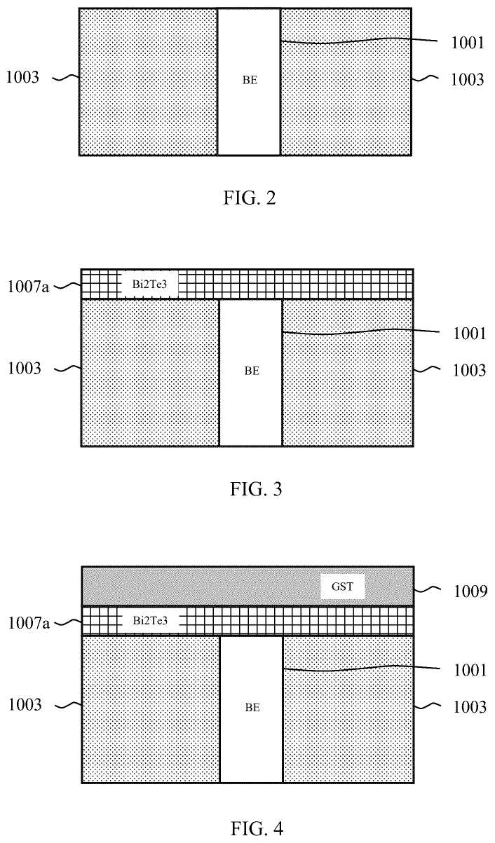

Referring now to FIGS. 2-5, according to some aspects, in the method of manufacturing a phase change memory cell, according to the embodiment of FIG. 1, a first electrode 1001 (e.g., bottom electrode) can be formed embedded in an insulator 1003, as shown in FIG. 2. The insulator 1003 can include silicon nitride or oxide, which are insulators that can hold a charge well.

The surface of the first electrode 1001 and the insulator 1003 can be prepared. For example, the surface can be cleaned and electrically charged with Ar sputtering (e.g., with Argon that is ionized), or an electron beam, as an example. As illustrated in FIG. 3, a first layer of thermoelectric material 1007a, such as Bismuth—Telluride (e.g., Bi₂Te₃ or other ratios of Bismuth to Telluride), though examples are not so limited and other thermoelectric materials can be contemplated (e.g., TiTe₂, Sb₂Te₃ etc.), can be deposited on the cleaned and electrically charged surface of the first electrode 1001 and the insulator 1003. The first layer of thermoelectric material 1007a can be a seed layer, deposited at an elevated or high temperature, onto the charged surface. As such, the first layer of thermoelectric material 1007a can be a highly oriented seeding layer. The highly oriented, thermoelectric material, seed layer 1007a can be a crystalline seed layer with a crystalline z-axis orientation perpendicular to the surface of the first electrode 1001. Thus, in one or more embodiments, the highly oriented seed layer is not a single crystal; rather, it has crystallites, but they are all largely oriented in the same way, at least in one dimension/axis.

Turning now to FIG. 4, a layer of phase change material (PCM) 1009, such as Germanium—Antimony—Tellurium (GeSbTe or GST), though examples are not so limited, can be deposited on the highly oriented, thermoelectric material, seed layer 1007a. The highly oriented, thermoelectric material, seed layer 1007a can facilitate growth of a fiber-textured PCM 1009 (i.e., a fiber-textured GST material). That is, the crystalline seed layer (i.e., highly oriented, thermoelectric material, seed layer 1007a) with the crystalline z-axis orientation perpendicular to the surface of the first electrode 1001 and oriented in the same direction can facilitate orientation of the crystallites within the PCM 1009 in a same direction. As such, the Bi₂Te₃ layer 1007a can be used to orientate the GST layer 1009. Accordingly, the PCM 1009 can be grown in such a way that it is highly oriented, following a template of the seed layer. That is, the PCM 1009 (i.e., GST layer), when crystalline, is not in a random order or polycrystalline (e.g., as it has not been sputtered and then annealed without a template seed layer) but can follow the template of the highly oriented, thermoelectric material, seed layer 1007a (i.e., Bi₂Te₃ layer) and thus be a highly oriented PCM 1009 layer. Note:
If the PCM 1009 film is sputtered at room temperature over a seed layer 1007a (which is a highly oriented seed layer), and later PCM 1009 film is annealed, PCM 1009 can be oriented. This solid phase (rather than gas phase) templating of PCM layer 1009 can lead to a PCM 1009 film with fiber texture which follows that of seed layer 1007a.

Accordingly, in one or more embodiments, the PCM 1009 can be epitaxially grown on the highly oriented, thermoelectric material, seed layer 1007a, obtaining a structure with van der Waals gaps. That is, the material can grow epitaxially with covalent bonds, and after a certain number of atomic layers, it can form a “satisfied layer” that is held to the next layer, not by covalent bonding but by van der Waals forces, so that there is literally a gap. Such embodiments can increase thermal and electrical resistance due to the formation of the van der Waals interfaces/gaps. Further, a thermoelectric junction can be formed between the thermoelectric material 1007a and the PCM 1009.

Advantageously, as is described in further detail herein, orientating the crystallites of the PCM 1009 in the same direction can lead to a lower or reduced reset current/a lower pulse amplitude in order to reset the device.

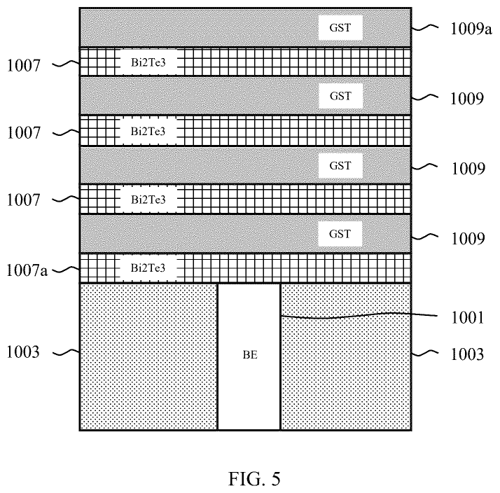

In some embodiments, multiple alternating layers of thermoelectric material 1007 and PCM 1009 can be deposited on the first electrode 1001 and the insulator 1003, as illustrated in FIG. 5. That is, a superlattice of alternating thermoelectric material 1007 and PCM 1009 can formed. As such, multiple thermoelectric junctions can be formed between the thermoelectric materials 1007 and PCMs 1009. The last layer deposited can be a PCM layer 1009a. Accordingly, the thermoelectric material 1007 and PCM 1009 can alternate throughout the PCM cell 1000 with the first layer being a thermoelectric material 1007a deposited directly on the first electrode 1001 and the insulator 1003 and the last layer being the PCM 1009a.

Referring now back to FIG. 1. A second electrode 1005 (e.g., top electrode), as shown in FIG. 1, can be deposited on the last layer of the PCM 1009a. The second electrode 1005 can be larger than the first electrode 1001. In some embodiments, the second electrode 1005 can extend across the whole PCM cell 1000. Though not illustrated in the figures, in some embodiments, the PCM cell 1000 can be located in a back-end-of-line (BEOL) wiring layer of a semiconductor device, the access transistors having been previously formed during front end of line (FEOL) processing.

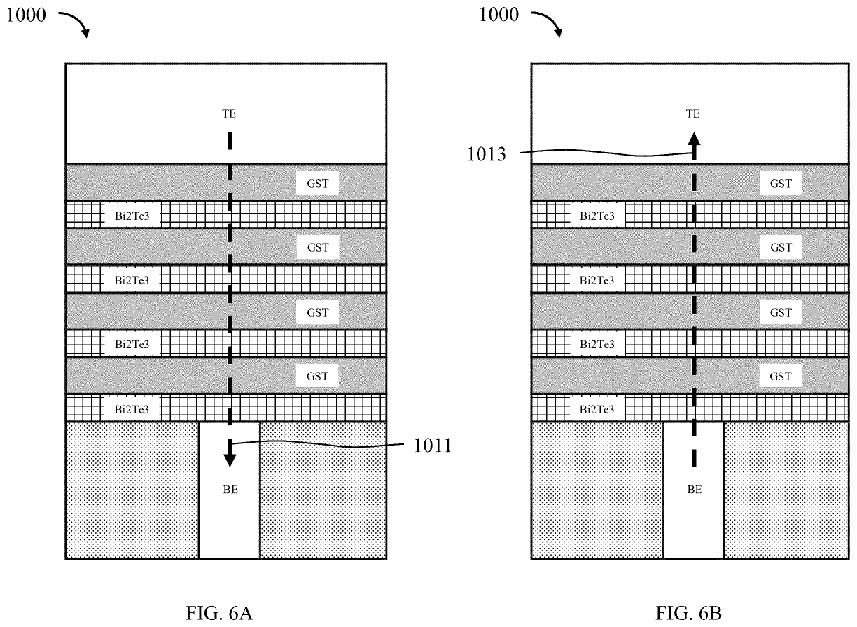

Turning now to FIGS. 6A and 6B, current directionality or polarity, dependent on a write operation or a read operation on a PCM cell 1000, is illustrated. FIG. 6A illustrates a current directionality or polarity of the PCM cell 1000 during a write operation. The direction of current flow, as illustrated in FIG. 6A, can have a first polarity 1011. In some embodiments, the first polarity 1011 can cause a current pulse to flow from an electrode (e.g., top electrode 1005 as illustrated in FIG. 1) through alternating layers of PCM 1009 (e.g., GST, as numbered in the previous figures) and thermoelectric material 1007 (e.g., Bi₂Te₃, as numbered in the previous figures) to another electrode (e.g., bottom electrode 1001 as illustrated in FIGS. 1-5), in which the first layer in which current flows through is a PCM 1009, the second layer is a thermoelectric material 1007, and the following layers continue in an alternating pattern of PCM 1009 and thermoelectric material 1007 layers. FIG. 6A illustrates four pairs of alternating layers; however, examples are not so limited and greater or fewer than four pairs of alternating layers can be contemplated.

Further, FIG. 6B illustrates a current directionality or polarity of the PCM cell 1000 during a read operation. The direction of current flow, as illustrated in FIG. 6B, can have a second polarity 1013. In some embodiments, the second polarity 1013 can cause a current pulse to flow from an electrode (e.g., bottom electrode 1001 as illustrated in FIGS. 1-5) through alternating layers of thermoelectric material 1007 (e.g., Bi₂Te₃, as numbered in the previous figures) and PCM 1009 (e.g., GST, as numbered in the previous figures) to another electrode (e.g., top electrode 1005 as illustrated in FIG. 1), in which the first layer in which current flows through is a thermoelectric material 1007, the second layer is a PCM 1009, and the following layers continue in an alternating pattern of thermoelectric material 1007 and PCM 1009 layers. FIG. 6B illustrates four pairs of alternating layers; however, examples are not so limited and greater or fewer than four pairs of alternating layers can be contemplated.

During operation of the PCM cell, the programming region (i.e., the amorphous-crystalline phase transformation region) can form a mushroom-like shape, as shown in FIG. 7. That is, during programming, a dome 1015 of amorphous PCM material can be formed. The dome 1015 and bottom electrode 1001 together can form a “mushroom-like” shape where the bottom electrode 1001 resembles a stem of the mushroom and the dome 1015 resembles the mushroom. Note that with some thermoelectric material the seed layer has disappeared under the region 1015 due to intermixing in the melt, while the seed/templating layer 1007a remains under the crystalline PCM layer 1009. This intermixing depends on the material used for the seed layer. A size of the dome 1015 can depend upon an amplitude of the RESET pulse. In some embodiments, the size of the dome 1015 can reach a radius of about 40-50 nm for a strong RESET, though examples are not so limited. As previously described, the dome 1015 of amorphous PCM can re-crystallize upon a SET pulse using the surrounding crystalline PCM material as a template.

Refer now to FIG. 8A. View 1299 shows a phase change memory array; only a 2 by 2 array is shown but any suitable number of cells can be employed. The appropriate word line 1279 selects which bit it is desired to read or write. The word line 1279 connects to the gate of a transistor 1277. The gate of the transistor 1277 provides an electrical switching function. The drain of the transistor 1277 is connected to one terminal of the memory element 1275 (e.g., cell 1000), while the other terminal of the memory element 1275 is connected to a corresponding bit line 1273. The source of the switch (transistor 1277) is connected to ground.

There are many ways to read the bit. For example, the bit line 1273 can be charged to some voltage and then kept floating, and the word line 1279 can be set to high which opens the switch 1277, allowing current to flow from the bit line 1273 to the ground through the memory element 1275. If the memory element 1275 is in RESET phase, the bit line 1273 will remain charged, since little current will flow due to the PCM high resistance. But if the PCM 1009 is in SET phase, then the bit line 1273 will discharge, since the PCM 1009 is at low resistance, and the voltage on the bit line 1273 will approach zero. A sensing amplifier can be used to detect the voltage on the bit line 1273 to determine if the bit read was a “0” or a “1.”

To write the bit, the bit is selected by applying a voltage to the word line 1279 and then pulsing the bit line 1273 with a SET or a RESET pulse.

FIG. 8B (View 1297) shows a crossbar array for AI computation; the general structure of such an array, using prior-art memory cells, is known from the IBM Research Paper by Abu Sebastian, Manuel Le Gallo, Geoffrey W. Burr, Sangbum Kim, Matthew BrightSky, and Evangelos Eleftheriou, “Tutorial: Brain-inspired computing using phase-change memory devices,” Journal of Applied Physics 124, no. 11 (2018 Sep 21), pages 111101-1 to 111101-1. Voltage is applied on the input lines 1206, and the currents from each PCM element 1202 (i.e., PCM cell 1000 as shown in FIG. 1, FIG. 6A, FIG. 6B, and FIG. 7) are summed in the output lines 1210. Following Ohm's law, the current in each element 1202 is V(j)×G(k, j), where G is the conductance of element (k, j). Conductance is 1/R, or one over the resistance of the PCM element 1202. A crossbar array such as 1297 can be used for analog AI computation; there are no “bits” but weights. The weights are not “0” and “1,” but any value of conductance between SET conductance and RESET conductance.

So, as a result, by Kirchhoff's circuit laws the output lines 1210 are the sum of the products of the input voltages times the conductance of the array elements. Effectively this crossbar array can implement a multiply accumulate (MAC) operation which is a very common operation for the computation of artificial neural networks. A crossbar array can therefore be used to accelerate AI computation. Note the transistors 1203 are used to prevent the read current from flowing through another bit which is in SET phase to another output line 1210. Suppressing unwanted current flow in unselected cells is referred to as “sneak path” current.

To implement the matrix multiplication A*x using the crossbar array, the matrices elements Aij are mapped to the conductance values of the PCM cells, and vector x is mapped to the input voltage (V1, V2) in the example). The result (vector b) corresponds to the output currents (I1, I2, I3).

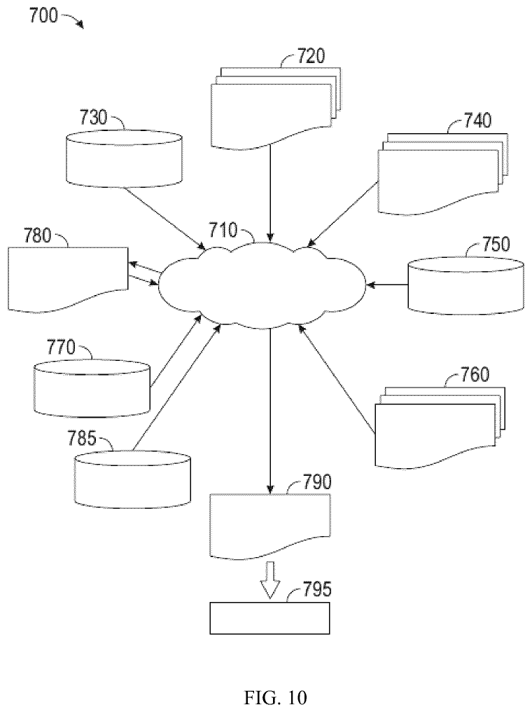

A large array of memory devices can be implemented on a single chip. An arbitrarily large number of cells 1202 or 1275 (i.e., PCM cell 1000 as shown in FIG. 1, FIG. 6A, FIG. 6B, and FIG. 7) can be employed, within the limits of the manufacturing processes and design specifications. FIG. 8B (View 1297) is an example of an analog AI application (multiplying A matrix 1295 by x vector 1293 to obtain output vector b 1291). A controller (e.g., known digital circuitry) and power supply 1289 are coupled to the array(s) and peripheral circuits in a known manner—crossbar arrays per se are well known; given the teachings herein, the skilled artisan can implement such an array with appropriate peripheral circuitry, controller, and power supply with inventive PCM cells as disclosed herein. The controller and power supply are shown as a combined unit 1289 but can be implemented as separate units if desired. Suitable digital circuitry to implement the controller and/or power supply 1289 can, given the teachings herein, be designed, synthesized, and fabricated using techniques such as discussed with respect to FIG. 10. In one or more embodiments, the purpose of this circuitry is to program the device by generating current pulses or read the device state using low current pulse.

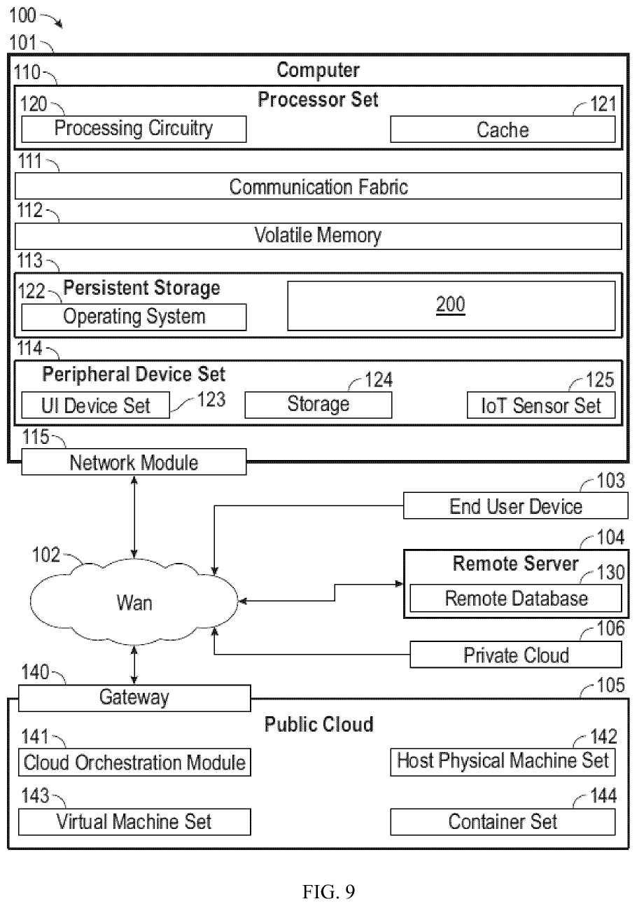

Reference should now be had to FIG. 9, which illustrates a computing environment according to an embodiment of the present invention (e.g., for implementing a design process such as that of FIG. 10).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium can be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system 200 for semiconductor design and/or control of semiconductor fabrication (see FIG. 10). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 can take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method can be distributed among multiple computers and/or between multiple locations. On the other hand, in this presentation of computing environment 100, detailed discussion is focused on a single computer, specifically computer 101, to keep the presentation as simple as possible. Computer 101 can be located in a cloud, even though it is not shown in a cloud in FIG. 9. On the other hand, computer 101 is not required to be in a cloud except to any extent as can be affirmatively indicated.

PROCESSOR SET 110 includes one, or more, computer processors of any type now known or to be developed in the future. Processing circuitry 120 can be distributed over multiple packages, for example, multiple, coordinated integrated circuit chips. Processing circuitry 120 can implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set can be located “off chip.” In some computing environments, processor set 110 can be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods can be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths can be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory can be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 can be a read only memory (ROM), but typically at least a portion of the persistent storage allows writing of data, deletion of data and re-writing of data. Some familiar forms of persistent storage include magnetic disks and solid state storage devices. Operating system 122 can take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 can be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 can include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 can be persistent and/or volatile. In some embodiments, storage 124 can take the form of a quantum computing storage device for storing data in the form of qubits. In embodiments where computer 101 is required to have a large amount of storage (for example, where computer 101 locally stores and manages a large database) then this storage can be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor can be a thermometer and another sensor can be a motion detector.

NETWORK MODULE 115 is the collection of computer software, hardware, and firmware that allows computer 101 to communicate with other computers through WAN 102. Network module 115 can include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 can be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers, and edge servers.

END USER DEVICE (EUD) 103 is any computer system that is used and controlled by an end user (for example, a customer of an enterprise that operates computer 101), and can take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 can be a client device, such as thin client, heavy client, mainframe computer, desktop computer, and so on.

REMOTE SERVER 104 is any computer system that serves at least some data and/or functionality to computer 101. Remote server 104 can be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data can be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs can be stored as images and can be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud can be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Exemplary Design Process Used in Semiconductor Design, Manufacture, and/or Test

One or more embodiments make use of computer-aided semiconductor integrated circuit design simulation, test, layout, and/or manufacture. In this regard, FIG. 10 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 can be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines can include: lithography machines, machines and/or equipment for generating masks (e.g., e-beam writers), computers or equipment for simulating design structures, any apparatus used in the manufacturing or test process, or any machines for programming functionally equivalent representations of the design structures into any medium (e.g., a machine for programming a programmable gate array).

Design flow 700 can vary depending on the type of representation being designed. For example, a design flow 700 for building an application specific IC (ASIC) can differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 10 illustrates multiple such design structures including an input design structure 720 that is preferably processed by a design process 710. Design structure 720 can be a logical simulation design structure generated and processed by design process 710 to produce a logically equivalent functional representation of a hardware device. Design structure 720 can also or alternatively include data and/or program instructions that when processed by design process 710, generate a functional representation of the physical structure of a hardware device. Whether representing functional and/or structural design features, design structure 720 can be generated using electronic computer-aided design (ECAD) such as implemented by a core developer/designer. When encoded on a gate array or storage medium or the like, design structure 720 can be accessed and processed by one or more hardware and/or software modules within design process 710 to simulate or otherwise functionally represent an electronic component, circuit, electronic or logic module, apparatus, device, or system. As such, design structure 720 can include files or other data structures including human and/or machine-readable source code, compiled structures, and computer executable code structures that when processed by a design or simulation data processing system, functionally simulate or otherwise represent circuits or other levels of hardware logic design. Such data structures can include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which can contain design structures such as design structure 720. Netlist 780 can include, for example, compiled or otherwise processed data structures representing a list of wires, discrete components, logic gates, control circuits, I/O devices, models, etc. that describes the connections to other elements and circuits in an integrated circuit design. Netlist 780 can be synthesized using an iterative process in which netlist 780 is resynthesized one or more times depending on design specifications and parameters for the device. As with other design structure types described herein, netlist 780 can be recorded on a machine-readable data storage medium or programmed into a programmable gate array. The medium can be a nonvolatile storage medium such as a magnetic or optical disk drive, a programmable gate array, a compact flash, or other flash memory. Additionally, or in the alternative, the medium can be a system or cache memory, buffer space, or other suitable memory.

Design process 710 can include hardware and software modules for processing a variety of input data structure types including Netlist 780. Such data structure types can reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types can further include design specifications 740, characterization data 750, verification data 760, design rules 770, and test data files 785 which can include input test patterns, output test results, and other testing information. Design process 710 can further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 can also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 720, design structure 790 preferably includes one or more files, data structures, or other computer-encoded data or instructions that reside on data storage media and that when processed by an ECAD system generate a logically or otherwise functionally equivalent form of one or more IC designs or the like. In one embodiment, design structure 790 can include a compiled, executable HDL simulation model that functionally simulates the devices to be analyzed.

Design structure 790 can also employ a data format used for the exchange of layout data of integrated circuits and/or symbolic data format (e.g., information stored in a GDSII (GDS2), GL1, OASIS, map files, or any other suitable format for storing such design data structures). Design structure 790 can include information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., . lib files). Design structure 790 can then proceed to a stage 795 where, for example, design structure 790: proceeds to tape-out, is released to manufacturing, is released to a mask house, is sent to another design house, is sent back to the customer, etc.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1(SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P.H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far (reference characters refer to the drawings discussed above), it will be appreciated that, in general terms, an exemplary phase change material (PCM) array 1297, 1299 includes a plurality of word lines 1279, a plurality of bit lines 1206, 1273, and a plurality of PCM cells 1202, 1275, (e.g., PCM cell 1000) in which each bit line 1206, 1273 is bridged to a word line 1279 by a PCM cell 1000, of the plurality of PCM cells 1202, 1275, (e.g., cell 1000) in series with a transistor 1203, 1277, and in which each PCM cell 1000 includes a plurality of layers of a thermoelectric material 1007 and a plurality of layers of a phase change material (PCM) 1009, in which one of the plurality of layers of the thermoelectric material 1007 is a highly oriented seeding layer 1007a and the plurality of layers of the thermoelectric material 1007 and the plurality of layers of the PCM 1009 are alternating layers within the PCM cell 1000. Technical benefits of a highly oriented, thermoelectric material, seeding layer 1007a include the ability to utilize the seeding layer as a template to grow a fiber-textured PCM 1009 on the highly oriented, thermoelectric material, seeding layer 1007a. Further, thermoelectric junctions can be formed between the alternating layers promoting either heating of the PCM cell 1000 or cooling of the PCM cell 1000 dependent upon the directionality of the current supplied through the PCM cell 1000.

Optionally, the thermoelectric material 1007 can be bismuth—telluride (Bi₂Te₃). Technical benefits of utilizing a bismuth—telluride thermoelectric material 1007 include a potential for lower reset currents and lower resistance drift within the device.

Further, optionally, the PCM 1009 can have a fiber-textured growth, facilitated by the highly oriented seeding layer 1007a, and the PCM 1009 can include van der Waals gaps. In some options, the PCM 1009 can be germanium—antimony—tellurium (GST). Technical benefits include an increase in thermal and electrical resistance due to the formation of the van der Waals interfaces/gaps, which can increase heating and energy efficiency during a write operation of the PCM cell 1000.

In further options, the PCM cell 1000 can include an even number of layers of the plurality of layers of the thermoelectric material 1007 and the plurality of layers of the PCM 1009. Technical benefits can be a promotion of either heating of the PCM cell 1000 or cooling of the PCM cell 1000, dependent upon the directionality of the current supplied through the PCM cell 1000, as current flows through multiple thermoelectric junctions formed between the alternating layers of the thermoelectric material 1007 and the PCM 1009.

Continuing with options, the PCM cell 1000 can include a bottom electrode 1001 and a top electrode 1005, in which the plurality of layers of the thermoelectric material 1007 and the plurality of layers of the PCM 1009 reside between the bottom electrode 1001 and the top electrode 1005. In some options, the bottom electrode 1001 can be smaller in area than the top electrode 1005. Technical benefits can include flowing current, through the alternating layers of thermoelectric material 1007 and PCM 1009, between the electrodes in order to write data into and/or read data from the PCM cell 1000. Further, a higher current density at the bottom electrode 1001 than the top electrode 1005, due to the smaller surface area of the bottom electrode 1001, can be observed. Typically, a smaller surface area (e.g., diameter) of the bottom electrode 1001 promotes a lower RESET current due to the higher current density. Thus, since a lower RESET current can result in a utilization of less energy to program the PCM cell 1000, technical benefits include a reduction in resource consumption, increasing efficiency and reducing operating cost. Additionally, PCM cells 1000 can be packed closer since generating less heat in a PCM cell 1000 can reduce the impact in adjacent cell.

Further, optionally, the PCM cell 1000 can include an insulator material 1003 directly adjacent to the bottom electrode 1001. As the top electrode 1005 can extend across the whole PCM cell 1000 and the bottom electrode 1001 can have a smaller surface area than the top electrode 1005, a technical benefit of the insulator material 1003 can include providing a surface area, in conjunction with the surface area of the bottom electrode 1001, that extends across the whole PCM cell 1000 and supports the alternating thermoelectric material 1007 and PCM 1009 layers. Another technical benefit of the insulator material 1003 includes confining heat generated by electrical pulses to the active areas of the bottom electrode 1001.

In optional further aspects, the one of the plurality of layers of the thermoelectric material that is the highly oriented seeding layer 1007a can be directly adjacent to the bottom electrode 1001 and one of the plurality of layers of the PCM 1009a can be directly adjacent to the top electrode 1005. Technical benefits of the highly oriented seeding layer 1007a can be directly adjacent to the bottom electrode 1001 can include utilizing the highly oriented seeding layer 1007a as a template to facilitate growth of the fiber-textured PCM 1009 in a highly oriented crystalline form.

In further options, the PCM array 1297, 1299 can include circuitry 1289 to cause a current pulse between the bottom electrode 1001 and the top electrode 1005, through the plurality of layers of the thermoelectric material 1007 and the plurality of layers of the PCM 1009. Optionally, in response to a request to perform a memory write operation, the circuitry 1289 can set a current polarity to generate electrothermal heating during the current pulse through the plurality of layers of the thermoelectric material 1007 and the plurality of layers of the PCM 1009. Technical benefits include assisting a write operation and reducing the RESET/SET current during the write operation of the PCM cell 1000, increasing energy efficiency.

Additionally, optionally, in response to a request to perform a memory read operation, the circuitry 1289 can set a current polarity to generate electrothermal cooling during the current pulse through the plurality of layers of the thermoelectric material 1007 and the plurality of layers of the PCM 1009. Technical benefits include cooling of the PCM cell 1000 during the read operation leading to an option to increase a current amplitude and/or increase a voltage applied, thus reducing potential occurrences of a read disturb during the read operation and improving a signal to noise ratio, and thus increasing reliability of the PCM cell 1000.

In accordance with further aspects of the invention, an exemplary method of operating a memory cell includes receiving, by circuitry 1289, a request to perform a memory write operation of a phase change memory (PCM) cell 1000; responsive to receiving the request to perform the memory write operation, selecting, by the circuitry 1289 a first polarity 1011 of a current pulse between a top electrode 1005 and a bottom electrode 1001 of the PCM cell 1000; receiving, by the circuitry 1289, a request to perform a memory read operation of the PCM cell 1000, and responsive to receiving the request to perform the memory read operation, selecting, by the circuitry 1289, a second polarity 1013 of the current pulse between the top electrode 1005 and the bottom electrode 1001 of the PCM cell 1000, in which selecting the first polarity 1011 of the current pulse can cause a superlattice of thermoelectric material 1007 of the PCM cell 1000 to heat the PCM cell 1000 and selecting the second polarity 1013 of the current pulse can cause the superlattice of thermoelectric material 1007 of the PCM cell 1000 to cool the PCM cell 1000. Technical benefits include an assist in a write operation and a reduction in RESET/SET current during the write operation of the PCM cell 1000, increasing energy efficiency, and optional increase of current amplitude and/or increase in voltage applied during a read operation, thus reducing potential occurrences of a read disturb, improving a signal to noise ratio, and increasing reliability of the PCM cell 1000.

Optionally, the first polarity 1011 of the current pulse can cause current to flow from the top electrode 1005 to the bottom electrode 1001, the bottom electrode 1001 being smaller than the top electrode 1005. Further, optionally, the second polarity 1013 of the current pulse can cause current to flow from the bottom electrode 1001 to the top electrode 1005, the bottom electrode 1001 being smaller than the top electrode 1005.

In further options, the method can further include, responsive to receiving the request to perform the memory write operation, selecting, by the circuitry 1289, a first current amplitude; responsive to receiving the request to perform the memory read operation, selecting, by the circuitry 1289, a second current amplitude; and applying to the PCM cell 1000, by a power supply 1289, a selected current amplitude. Optionally, the second current amplitude applied to the PCM cell 1000 during the memory read operation can be smaller than the first current amplitude applied to the PCM cell 1000 during the memory write operation. Technical benefits include a reduction in read disturb occurrences during a read operation as a higher current can cause the PCM cell 1000 to change phases, such as from amorphous to crystalline, resulting in an unintentional programing of the PCM cell 1000 during a read operation.

Further, optionally, the second current amplitude applied to the PCM cell 1000 during the memory read operation can be below a threshold current amplitude level. Technical benefits include preventing read errors due to the current amplitude being too low (e.g., below a threshold current amplitude level) and causing excessive noise, negatively affecting a signal to noise ratio, and causing read interference.

Generally, it is desirable to prevent changing the state of the device during the READ operation (read disturb)—it is desirable to determine what state the device is in when it is read, and not to change that state during the READ operation. That is why it is desirable that the READ current be below a level in which heat caused by the current could cause the state to go from a RESET state (amorphous) to a SET state (crystalline).

The current amplitude for a RESET operation depends on the size of the bottom electrode, among other factors. The smaller the bottom electrode, the lower the reset current needed. In a non-limiting example, with a device having a bottom electrode with a diameter of 40 nm, the reset current is about 300-400 μA (micro amps), and the read current is typically about 1-40 μA for devices in the SET state and about 0.04-0.4 μA in the RESET state.

In still further options, the method can include, responsive to receiving the request to perform the memory write operation, selecting, by the circuitry 1289, a first voltage value and responsive to receiving the request to perform the memory read operation, selecting, by the circuitry 1289, a second voltage value, in which the second voltage value can be less than the first voltage value.

In a non-limiting example, a typical voltage for a read operation is 0.2-0.4 V, while a typical write operation (when the device is in the RESET state) depends on the device threshold voltage. Usually, the threshold voltage is about 1-1.2 volts, so a large voltage is applied (e.g. 1.5 V). This is a non-limiting example, for GST based devices. Other PCM materials may have different threshold voltages. Further, how “hard” the device was programmed in the RESET state will impact the threshold voltage.

In yet another option, the method can include applying the current pulse between the top electrode 1005 and the bottom electrode 1001 through thermoelectric junctions, created between alternating layers of a bismuth—telluride (Bi₂Te₃) thermoelectric material 1007 and a germanium—antimony—tellurium (GST) phase change material (PCM) 1009, located between the bottom electrode 1001 and the top electrode 1005. Technical benefits can be a promotion of either heating of the PCM cell 1000 or cooling of the PCM cell 1000, dependent upon the directionality of the current pulse supplied through the PCM cell 1000, as current flows through multiple thermoelectric junctions formed between the alternating layers of the thermoelectric material 1007 and the PCM 1009.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from phase change memory cells with highly oriented PCM structure aligned to highly oriented, thermoelectric material, seed layer in phase change memory arrays, and the like.

An integrated circuit in accordance with aspects of the present inventions can be employed in essentially any application and/or electronic system where phase change memory cells with highly oriented PCM structure aligned to highly oriented, thermoelectric material, seed layer in phase change memory arrays, and the like, as disclosed herein, would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession can, in fact, be executed substantially concurrently, or certain steps can sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A phase change material (PCM) array comprising:
a plurality of word lines;
a plurality of bit lines; and
a plurality of PCM cells,
wherein each bit line is bridged to a word line by a PCM cell, of the plurality of PCM cells, in series with a transistor, and
wherein, each PCM cell comprises:
a plurality of layers of a thermoelectric material; and
a plurality of layers of a phase change material (PCM),
wherein:
one of the plurality of layers of the thermoelectric material is a highly oriented seeding layer; and
the plurality of layers of the thermoelectric material and the plurality of layers of the PCM are alternating layers within the PCM cell.

2. The PCM array of claim 1, wherein the thermoelectric material is bismuth—telluride (Bi₂Te₃).

3. The PCM array of claim 1, wherein the PCM has a fiber-textured growth, facilitated by the highly oriented seeding layer, and the PCM includes van der Waals gaps.

4. The PCM array of claim 1, wherein the PCM is germanium—antimony—tellurium (GST).

5. The PCM array of claim 1, wherein the PCM cell comprises an even number of layers of the plurality of layers of the thermoelectric material and the plurality of layers of the PCM.

6. The PCM array of claim 1, wherein the PCM cell further comprises a bottom electrode and a top electrode, wherein the plurality of layers of the thermoelectric material and the plurality of layers of the PCM reside between the bottom electrode and the top electrode.

7. The PCM array of claim 6, wherein the bottom electrode is smaller in area than the top electrode.

8. The PCM array of claim 6, wherein the PCM cell further comprises an insulator material directly adjacent to the bottom electrode.

9. The PCM array of claim 6, wherein the one of the plurality of layers of the thermoelectric material that is the highly oriented seeding layer is directly adjacent to the bottom electrode and one of the plurality of layers of the PCM is directly adjacent to the top electrode.

10. The PCM array of claim 6, further comprising circuitry to cause a current pulse between the bottom electrode and the top electrode, through the plurality of layers of the thermoelectric material and the plurality of layers of the PCM.

11. The PCM array of claim 10, wherein, in response to a request to perform a memory write operation, the circuitry sets a current polarity to generate electrothermal heating during the current pulse through the plurality of layers of the thermoelectric material and the plurality of layers of the PCM.

12. The PCM array of claim 10, wherein, in response to a request to perform a memory read operation, the circuitry sets a current polarity to generate electrothermal cooling during the current pulse through the plurality of layers of the thermoelectric material and the plurality of layers of the PCM.

13. A method of operating a memory cell, the method comprising:
receiving, by circuitry, a request to perform a memory write operation of a phase change memory (PCM) cell;
responsive to receiving the request to perform the memory write operation, selecting, by the circuitry, a first polarity of a current pulse between a top electrode and a bottom electrode of the PCM cell;
receiving, by the circuitry, a request to perform a memory read operation of the PCM cell; and
responsive to receiving the request to perform the memory read operation, selecting, by the circuitry, a second polarity of the current pulse between the top electrode and the bottom electrode of the PCM cell,
wherein selecting the first polarity of the current pulse causes a superlattice of thermoelectric material of the PCM cell to heat the PCM cell and selecting the second polarity of the current pulse causes the superlattice of thermoelectric material of the PCM cell to cool the PCM cell.

14. The method of claim 13, wherein the first polarity of the current pulse causes current to flow from the top electrode to the bottom electrode, the bottom electrode being smaller than the top electrode.

15. The method of claim 13, wherein the second polarity of the current pulse causes current to flow from the bottom electrode to the top electrode, the bottom electrode being smaller than the top electrode.

16. The method of claim 13, further comprising:
responsive to receiving the request to perform the memory write operation, selecting, by the circuitry, a first current amplitude;
responsive to receiving the request to perform the memory read operation, selecting, by the circuitry, a second current amplitude; and
applying to the PCM cell, by a power supply, a selected current amplitude.

17. The method of claim 16, wherein the second current amplitude applied to the PCM cell during the memory read operation is smaller than the first current amplitude applied to the PCM cell during the memory write operation.

18. The method of claim 16, wherein the second current amplitude applied to the PCM cell during the memory read operation is below a threshold current amplitude level.

19. The method of claim 13, further comprising:
responsive to receiving the request to perform the memory write operation, selecting, by the circuitry, a first voltage value; and
responsive to receiving the request to perform the memory read operation, selecting, by the circuitry, a second voltage value, wherein the second voltage value is less than the first voltage value.

20. The method of claim 13, further comprising applying the current pulse between the top electrode and the bottom electrode through thermoelectric junctions, created between alternating layers of a bismuth—telluride (Bi₂Te₃) thermoelectric material and a germanium—antimony—tellurium (GST) phase change material (PCM), located between the bottom electrode and the top electrode.
